(19) United States
(12) Patent Application Publication
(10) Pub. No.: US 2009/0184404 A1
(43) Pub. Date: Jul. 23, 2009

(54) Electromagnetic shilding structure and manufacture method for multi-chip package module

(76) Inventor: En-Min Jow, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/149,285

(22) Filed: Apr. 30, 2008

(30) Foreign Application Priority Data
Jan. 17, 2008 (TW) 97101764

(51) Int. Cl. H01L 23/552; H01L 21/56

(52) U.S. Cl. 257/659; 438/107; 257/E23.114; 257/E21.502

(57) ABSTRACT

An electromagnetic shielding structure for a multi-chip package module includes a substrate having at least one conductive point, a plurality of chips, an encapsulating body and an electromagnetic shielding layer. Wherein the chips are arranged and encapsulated by the encapsulating body on the substrate. The electromagnetic shielding layer is arranged on the encapsulating body and the conductive point to shield highly frequency electromagnetic wave by printing. Meanwhile, the electromagnetic shielding layer can replace the conventional metal shell to reduce the whole size of the multi-chip package module.

### BACKGROUND OF THE INVENTION

1. Field of the Invention

The present invention is relates to an electromagnetic shielding structure and manufacture method for multi-chip package module, and more especially relates to form an electromagnetic shielding layer for the electromagnetic shielding structure of multi-chip package module by printing method.

2. Description of the Prior Art

Due to the growth of the electronic field is prosperity, most electronic products are developed toward miniaturization and high-speed. Especially, the communication industry field has been developed and applied to be integrated into various electronic products popularly, for example, cell phone, laptop and so on. However, in the afore-mentioned electronic products must use RF chip with highly frequency, and the RF chip may be adjacently arranged with the digital integrated circuit, the digital signal processor (DSP) or the base-band chip such that the electromagnetic interference phenomenon may be occurred. Thereby, the electromagnetic shielding process may be preformed.

Illustratively, FIG. 1 is a schematic diagram illustrating a conventional electronic shielding structure of multi-chip module. As FIG. 1 shown, the multi-chip module includes a substrate 12, a first chip 14A, a second chip 14B, a third chip 14C and a metallic shell 16, wherein the first chip 14A, the second chip 14B and the third chip 14C are encapsulated by an encapsulating body 18 and arranged on the substrate 12 respectively. Due to the first chip 14A, the second chip 14B, the third chip 14C have highly frequency characteristic as to be arranged the metallic shell 16 on the first chip 14A, the second chip 14B and the third chip 14C for achieving the electromagnetic shielding effect. However, the metallic shell 16 may cause the whole thickness of the multi-chip module 10 too height to meet the requirement of the miniaturization.

Moreover, FIG. 2 is an another schematic diagram illustrating a package structure for preventing from electromagnetic interference which includes a metal layer 20, a plurality of via holes 22 and a dielectric layer 24. The dielectric layer 24 is arranged on the upper surface of the metallic layer 20, and a chip 26 is arranged on the dielectric layer 24 such that the chip 26 is electrically connected to the metallic layer 20 through the via holes 22. Thereby, the bending method for manufacturing metallic layer 20 can achieve the highly thermal dissipation and electromagnetic shielding effect.

However, the above-mentioned package structure must bend the metallic layer 20 and may need the adhesive glue 28 to be connected with the dielectric layer 24 and chip 26. Meanwhile, from foregoing description, the package structure must use bending step, adhesion step and other steps to complete it. Thereby, the production time and manufacturing cost may be wasted, and the height of whole package structure still can not be diminished.

### SUMMARY OF THE INVENTION

In order to solve the above-mentioned problems, one of object of the present invention is to provide an electromagnetic shielding structure and manufacture method for a multi-chip package module which isolates from the electromagnetic with highly frequency by a printed electromagnetic shielding layer.

In order to solve the above-mentioned problems, another object of the present invention is to provide an electromagnetic shielding structure and manufacture method for a multi-chip package module, which replaces conventional metallic shell by a printed electromagnetic shielding layer to reduce the whole size of multi-chip package module.

To achieve the above-mentioned purposes, one embodiment of present invention is to provide a manufacture method for a multi-chip package module with an electromagnetic shielding structure, which comprising: providing a substrate with at least one conductive point; arranging a plurality of chips on the substrate to electrically connect with the substrate; sealing, the chips on the substrate with an encapsulating body; printing an electromagnetic shielding layer on the encapsulating body and the substrate; and electrically connecting with the electromagnetic shielding layer and the conductive point to isolate the electromagnetic wave with highly frequency.

To achieve the above-mentioned purposes, one embodiment of present invention is to provide an electromagnetic shielding structure for a multi-chip package module including: a substrate having at least one conductive point; a plurality of chips arranged on and electrically connected with the substrate; an encapsulating body sealing the chips on the substrate; and an electromagnetic shielding layer printed on the encapsulating body and the conductive point to isolate the electromagnetic wave with highly frequency.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a schematic diagram illustrating a conventional electromagnetic shielding structure of multi-chip module;

FIG. 2 is an another schematic diagram illustrating a conventional electromagnetic shielding structure of multi-chip module;

FIG. 3, FIG. 4, FIG. 5 and FIG. 6 are schematic diagrams illustrating a manufacture method for a multi-chip package module with an electromagnetic shielding structure according to one embodiment of present invention; and

FIG. 7 is a flowchart diagram illustrating a manufacture method for a multi-chip package module with an electromagnetic shielding structure according to present invention.

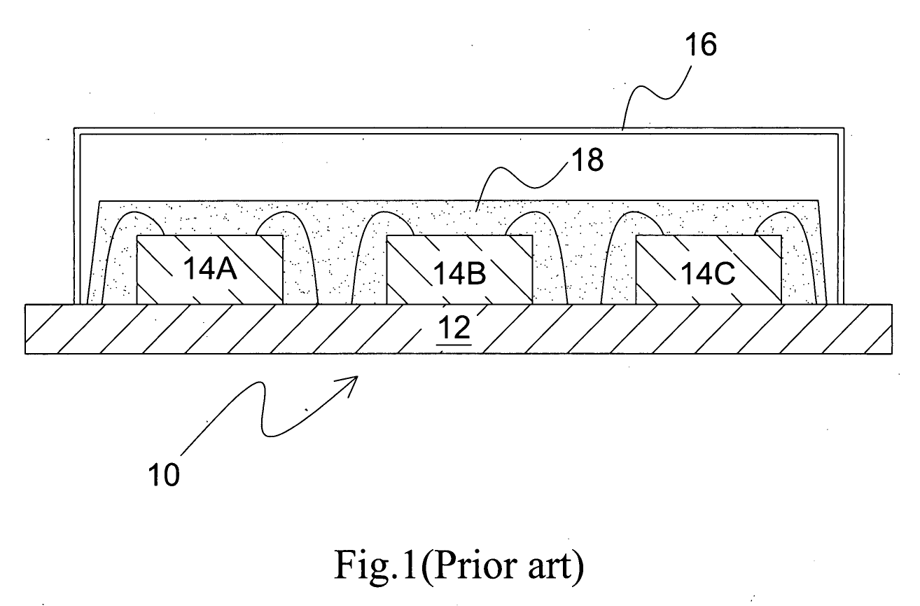

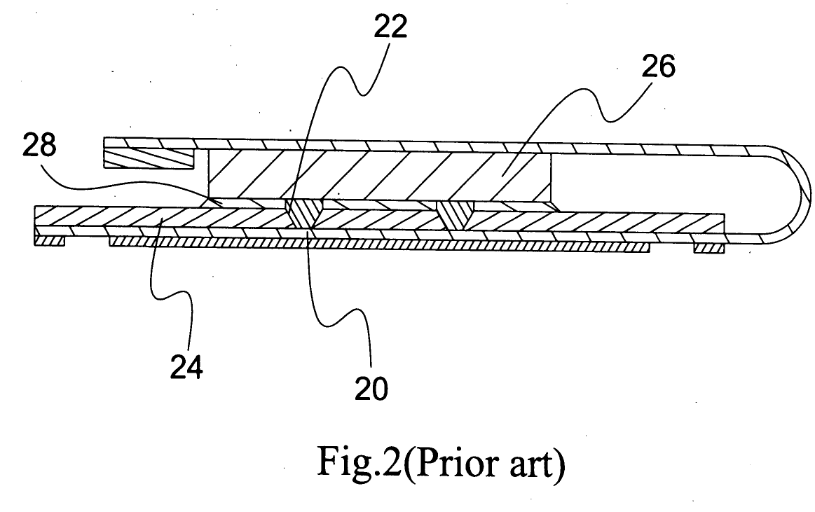

### DESCRIPTION OF THE PREFERRED EMBODIMENT

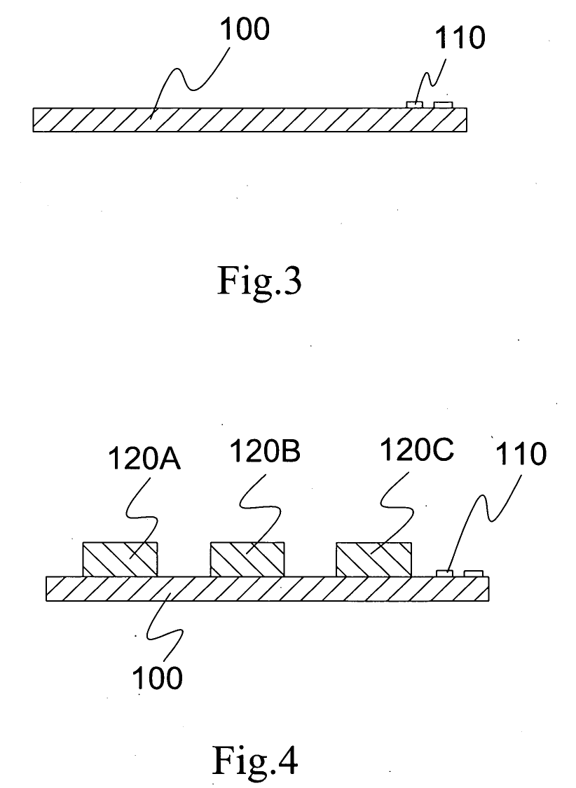

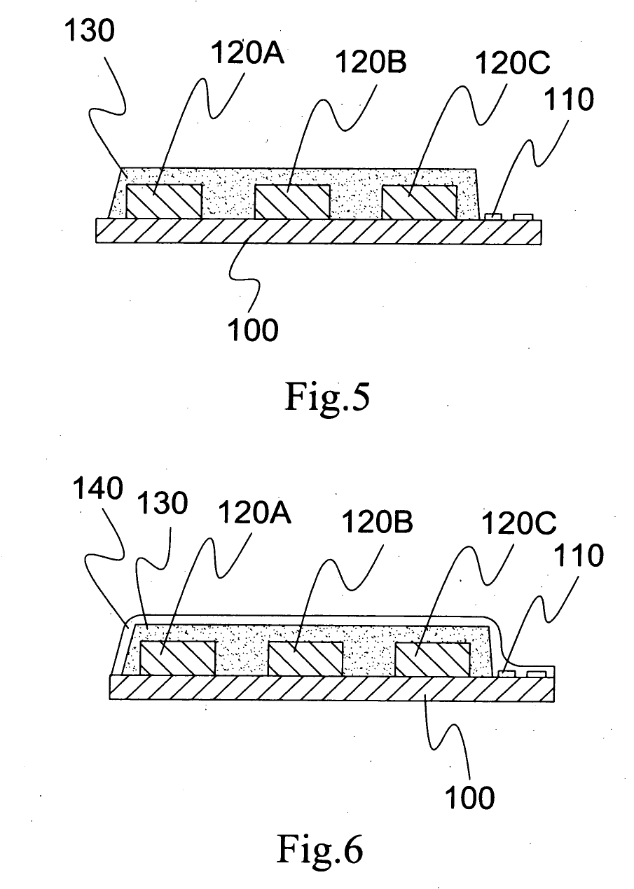

FIG. 3, FIG. 4, FIG. 5 and FIG. 6 are schematic diagrams illustrating a manufacture method for a multi-chip package module with an electromagnetic shielding structure according to one embodiment of present invention.

Firstly, as FIG. 3 shown, a substrate 100 with at least one conductive point 110 is provided. Next, as FIG. 4 shown, a plurality of chips 120A, 120B, 120C are arranged on and electrically connected to the substrate 100. Then, as FIG. 5 shown, an encapsulating body 130 is provided to seal the chips 120A, 120B, 120C on the substrate 100. Finally, as FIG. 6 shown, an electromagnetic shielding layer 140 may be formed on the encapsulating body 130 and the conductive point 110 by printing. Moreover, the electromagnetic shielding layer 140 and the conductive point 110 are electrically connected for grounding so as to release electromagnetic wave to the external of the multi-chip package module. Thereby, the electromagnetic shielding layer 140 and the conductive point 110 of the multi-chip package module can isolate and release the electromagnetic wave with highly frequency.

In a preferred embodiment, the electromagnetic shielding layer may be continually and simultaneously coated on the multi-chip module by inkjet printing. Besides, the size of the substrate is larger than an encapsulated range by the encapsulating body such that the substrate has an enough space to arrange the conductive point. In addition, the electromagnetic shielding layer may be printed on the multi-chip module by a printer which is inputted the required data of the specific electromagnetic shielding portion. On other words, the users can layout the optimal electromagnetic shielding area on the multi-chip module by printing where the chips may generate or be interfered with the electromagnetic wave.

In a preferred embodiment, the electromagnetic shielding layer may be a granular-shaped metallic material. In another preferred embodiment, a conductive line is arranged to electrically connect to the electromagnetic shielding layer and the conductive point for the purpose of grounding.

Accordingly, the chips may be RF chips, digital integrated circuits, base-band chips, digital signal processors (DSP) or the combinations thereof. On the other hands, the multi-chip package may be a wireless signal transceiver device, for example, a wireless network card, an optical transceiver module and so on.

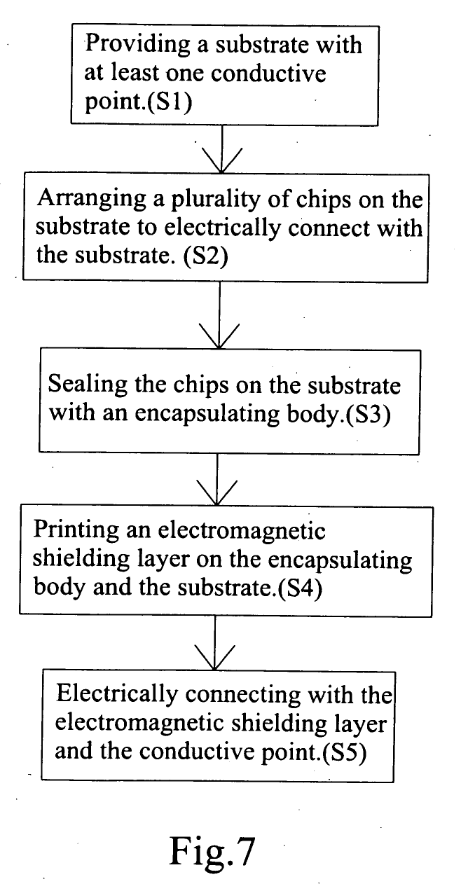

Please refer to FIG. 7 shown a flowchart diagram illustrating a manufacture method for a multi-chip package module with an electromagnetic shielding structure according to present invention, which includes: providing a substrate with at least one conductive point(S1); arranging a plurality of chips on the substrate to electrically connect with the substrate(S2); sealing the chips on the substrate with an encapsulating body(S3); printing an electromagnetic shielding layer on the encapsulating body and the substrate(S4); electrically connecting with the electromagnetic shielding layer and the conductive point(S5).

Please refer to FIG. 6 again, which is an electromagnetic shielding structure for the multi-chip package module according to present invention including: a substrate 100, a conductive point 110, a plurality of chips 120A, 120B and 120C, an encapsulating body 130 and an electromagnetic shielding layer 140, wherein the conductive point 110 is arranged on the substrate 100; the chips 120A, 120B, 120C are arranged on and electrically connected with the substrate 100; the encapsulating body 130 sealing the chips 120A, 120B, 120C on the substrate 100; and, the electromagnetic shielding layer 140 printed on the encapsulating body 130 and the conductive point 110.

In a preferred embodiment, the electromagnetic shielding structure for the multi-chip package module further includes a conductive line to electrically connect to the electromagnetic shielding layer and the conductive point for releasing the electromagnetic wave with highly frequency. In another preferred embodiment, the substrate is arranged in a ball grid array to electrically connect the chips.

To sum up, the electromagnetic shielding structure and manufacture method for the multi-chip package module according to the present invention isolates the electromagnetic wave with highly frequency by a printed electromagnetic shielding layer and so as to reduce the whole size of the multi-chip package module.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A manufacture method for multi-chip package module with electromagnetic shielding structure comprising:
providing a substrate with at least one conductive point;
arranging a plurality of chips on the substrate to electrically connect with the substrate;
sealing the chips on the substrate with an encapsulating body;
printing an electromagnetic shielding layer on the encapsulating body and the substrate; and
electrically connecting with the electromagnetic shielding layer and the conductive point.

2. The manufacture method for multi-chip package module with electromagnetic shielding structure according to claim 1, wherein the electromagnetic shielding layer is formed on the encapsulating body by inkjet printing.

3. The manufacture method for multi-chip package module with electromagnetic shielding structure according to claim 1, wherein the chips are RF chips, digital intergraded circuits, base-band chips, digital signal processors or the combinations thereof.

4. The manufacture method for multi-chip package module with electromagnetic shielding structure according to claim 1, wherein a size of the substrate is larger than an encapsulated range by the encapsulating body.

5. The manufacture method for multi-chip package module with electromagnetic shielding structure according to claim 1, wherein the multi-chip package module is a wireless network card, a wireless signal transceiver device or an optical transceiver module.

6. The manufacture method for multi-chip package module with electromagnetic shielding structure according to claim 1, wherein the electromagnetic shielding layer is a granular-shaped metallic material.

7. The manufacture method for multi-chip package module with electromagnetic shielding structure according to claim 1 further comprising electrically connecting a conductive line with both the electromagnetic shielding layer and the conductive point by wiring bond step.

8. An electromagnetic shielding structure for multi-chip package module comprising:
a substrate having at least one conductive point;
a plurality of chips arranged on and electrically connected with the substrate;
an encapsulating body sealing the chips on the substrate; and
an electromagnetic shielding layer printed on the encapsulating body and the conductive point.

9. The electromagnetic shielding structure for multi-chip package module according to claim 8, wherein the chips are RF chips, digital integrated circuits, base-band chips, digital signal processors or the combinations thereof.

10. The electromagnetic shielding structure for multi-chip package module according to claim 8, wherein the chips are electrically connected with the substrate by a plurality of wires.

11. The electromagnetic shielding structure for multi-chip package module according to claim 8, wherein the substrate is arranged in a ball grid array to electrically connect the chips.

12. The electromagnetic shielding structure for multi-chip package module according to claim 8, wherein the electromagnetic shielding layer is a granular-shaped metallic material.

13. The electromagnetic shielding structure for multi-chip package module according to claim 8, wherein a size of the substrate is larger than an encapsulated range by the encapsulating body.
